(19) United States
(12) Patent Application Publication
(10) Pub. No.: US 2020/0008310 A1
(43) Pub. Date: Jan. 2, 2020

(54) METHODS AND APPARATUS FOR PROVIDING IMPROVED VISUAL FEATURES ON A SUBSTRATE

(71) Applicant: CORNING INCORPORATED, CORNING, NY (US)

(72) Inventors: Matthew Wade Fenton, Elmira, NY (US); Timothy James Kiczenski, Corning, NY (US)

(21) Appl. No.: 16/456,684

(22) Filed: Jun. 28, 2019

Related U.S. Application Data
(60) Provisional application No. 62/691,122, filed on Jun. 28, 2018.

(51) Int. Cl. H05K 5/02; B41M 5/00; H05K 5/00; H05K 5/03; B44F 1/06

(52) U.S. Cl. CPC H05K 5/0243; B41M 5/0047; B41M 5/007; G06F 1/1626; H05K 5/0017; H05K 5/03; B44F 1/06; B41M 5/0064

(57) ABSTRACT

Methods and apparatus provide for improved visual features on a visible element of an article, such as a consumer electronic device.

### CROSS-REFERENCE TO RELATED APPLICATION

This application claims the benefit of priority under 35 U.S.C. § 119 of U.S. Provisional Application Ser. No. 62/691122 filed on Jun. 28, 2018, the content of which is relied upon and incorporated herein by reference in its entirety.

### BACKGROUND

The present disclosure relates to methods and apparatus for providing improved visual features on a substrate, such as on a substrate used in a commercial article.

As the sophistication of consumers continues to evolve and increase, the importance of aesthetic features, especially the integration of form and function, also increases. This is evident in the field of consumer electronics, such as in the design of mobile electronic devices (such as, mobile phones, smartphones, watches tablets, phablets, notebook computers, laptops, other types of computers, navigation systems, and the like). There have been many instances in which a consumer electronic device that exhibits some enhanced aesthetic feature over competing devices will enjoy significantly higher acceptance in the marketplace, even when the devices exhibit relatively comparable functional characteristics.

For example, there have been efforts in the marketplace to add a visual element, such as an image or color feature, to some surface(s) of an electronic device, such as to the back side of a mobile phone (and/or any of the other devices mentioned herein). A previously employed approach to achieving the visual element on an electronic device has been to apply ink (e.g., via ink jet printing) onto a substrate of the device. While consumers have come to accept, and even desire, such a visual element, a consistent issue with previous efforts is the visual element appears flat, unchanging, and therefore uninteresting to a viewer.

Accordingly, there are needs in the art for new methods and apparatus for providing visual features on a substrate.

### SUMMARY

The present disclosure relates to methods and apparatus for providing one or more improved visual features on a visible element (e.g., a substrate) of an article.

In accordance with one or more embodiments, an article may include some form of a housing in which functional elements of the article are disposed. For example, the housings of many smartphone devices include a touchscreen on a front side of the article and a substrate on the back side of the article. In rather basic configurations, the substrate on the back side of the article may be opaque, such as black or white. More interesting visual elements may include color, color and/or patterns, designs, images, etc.

In robust applications, such visual elements (especially printed elements, such as ink jet printed visual elements) may be disposed on an inner surface (e.g., an inwardly facing surface of the substrate or, in other words, a surface facing the interior of the housing) of a transparent (or partially transparent) substrate, such as a glass substrate, a glass-ceramic substrate, or a polymer substrate. Thus, the visual element may be seen by the user through the substrate but the visual element is protected from wear or damage by way of being disposed on the inwardly facing surface of the substrate.

The respective embodiments, individual features thereof, and/or sets of features thereof, disclosed and discussed herein are exemplary and may be provided alone or in any combination with any one or more other disclosed features without departing from the scope of the disclosure.

Other aspects, features, and/or advantages will be apparent to one skilled in the art from the description herein taken in conjunction with the accompanying drawings.

### DESCRIPTION OF THE DRAWINGS

For the purposes of illustration, there are forms shown in the drawings, it being understood, however, that the embodiments disclosed and described herein are not limited to the precise arrangements and instrumentalities shown.

FIG. 1 includes a top view and a perspective view of a substrate having one or more image features therewith;

FIGS. 2-3 are schematic diagrams of the substrate of FIG. 1 as it moves through a process for disposing one or of the image features thereon;

FIGS. 4A, 4B, and 4C are schematic diagrams of the substrate of showing additional details as it moves through the process for disposing one or of the image features thereon;

FIGS. 5A, 5B, 5C, and 5D are schematic diagrams of the substrate exhibiting certain light altering features in connection with the one or more image features;

FIG. 6 includes a perspective view of a substrate and supplemental substrate arrangement having one or more image features therewith;

FIG. 7 is a plan view of an exemplary electronic device incorporating any number of the improved image features disclosed herein; and

FIG. 8 is a perspective view of the exemplary electronic device of FIG. 7.

### DETAILED DESCRIPTION OF THE EMBODIMENTS

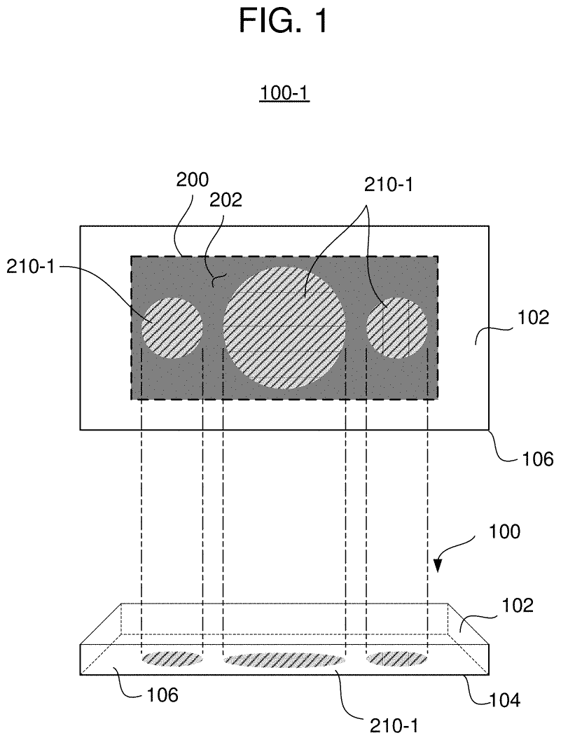

With reference to the drawings, wherein like numerals indicate like elements, there is shown in FIG. 1 an apparatus 100-1, primarily comprising a substrate 100, in accordance with one or more embodiments of this disclosure.

As mentioned above, among the applications of the apparatus 100-1 is to provide a visible element of an article, such as an electronic device, an architectural article, a transportation article, an appliance article, etc. In some embodiments, the substrate 100 of the apparatus 100-1 may also be a structural element of the article, such as forming part of a housing thereof. By way of example, the substrate 100 may be formed from glass material, glass-ceramic material, strengthened glass material, strengthened glass-ceramic material, and polymer material. When the substrate 100 is formed from strengthened glass (or glass-ceramic), such may be thermally strengthened or chemically-strengthened, for example via an ion-exchange process. The substrate 100 may exhibit substantial transparent characteristics, or may be partially transparent.

The substrate 100 includes a first major surface 102, a second major surface 104 opposite the first major surface 102, and at least one edge surface 106 extending between the first and second major surfaces 102, 104. By way of example, an article (e.g., a mobile electronics device) that comprises the apparatus 100-1 may include a housing within which components of the article are disposed, and wherein the first major surface 102 of the substrate 100 forms an outer surface of the housing. Thus, the user of the article may both see and touch the first major surface 102 of the substrate 100 when handling the housing of the article.

As previously mentioned, desirable characteristic(s) of the housing of the article include providing improved visual features via the first major surface 102 of the substrate 100. In this regard, the substrate 100 includes at least one visual element 210-1 disposed on the second major surface 104 of the substrate 100 such that the at least one visual element 210-1 may be viewed through the first major surface 102 thereof. By way of example, the at least one visual element 210-1 may include multiple circles (e.g., a larger circle flanked by two smaller circles) formed via color, lines, patterns, shading, design, etc.).

In one or more embodiments, the at least one visual element 210-1 is disposed on the second major surface 104 of the substrate 100 via an ink application process, such as an ink-jet printing process. It is noted, however, that other techniques may be employed in addition or in the alternative to dispose the at least one visual element 210-1 on the second major surface 104 of the substrate 100. For example, one or more films may be disposed on the second major surface 104 of the substrate 100, one or more other forms of pigment (e.g., paints, dyes, etc.).

The at least one visual element 210-1 may include one or more visual portions arranged into at least one of: (i) one or more areas of color, (ii) one or more lines, (iii) one or more patterns, (iv) one or more designs, (v) one or more images, or (vi) one or more combinations thereof. Those skilled in the art will appreciate that the particular artistic elements comprised within the at least one visual element 210-1 are seemingly infinite, and the illustrated example is not limiting.

The particular aesthetic elements employed in the example of the at least one visual element 210-1 as shown in FIG. 1 include some notable characteristics. In particular, the at least one visual element 210-1 may be defined as being within (or at least circumscribed by) an imaging area 200 of the second major surface 104 of the substrate 100. It is understood that the shape of the imaging area 200 (in this example a rectangle) is a matter of aesthetic choice, and is considered useful in connection with describing the embodiments herein. The size of the imaging area 200 is also a matter of aesthetic choice, and may or may not extend all the way to the peripheral edge of the substrate 100.

In addition, the at least one visual element 210-1 may be defined by a background 202 and a foreground. The foreground is understood to be defined as the visually dominant shapes of the at least one visual element 210-1 itself, in this example, the larger circle flanked by the two smaller circles. For purposes of discussion, the background 202 is considered to extend to the peripheral edge of the imaging area 200, which in FIG. 1 does not extend all the way to the peripheral edge of the substrate 100.

The background 202 includes at least some relatively higher optical density elements than one or more of the foreground elements. In the context of this disclosure, optical density is a quantity describing a magnitude of an image. By way of example, optical density may be expressed as log10 (1/R), where R is a reflectance factor, measured according with 0/45-degree geometry, Illuminant A, and ISO visual density calibration, see ISO/IEC 13660 (2001(E)). For example, the background 202 exhibits a characteristic of relatively high optical densities (e.g., a uniform dark grey) while the foreground elements (i.e., the three circles) exhibit characteristics of relatively lower optical densities (e.g., lighter grey and fine lines). It is, of course, the differences in optical densities of the background 202 and foreground elements that result in recognizable aesthetic features of the at least one visual element 210-1. As will be discussed in more detail later herein, the manner in which, and the techniques with which, the background 202 and foreground elements of the at least one visual element 210-1 are implemented result in very pleasing visual features and effects.

As will be discussed in greater detail later herein, the at least one visual element 210-1 may be printed on the second major surface 104 of the substrate 100, serving as an inner surface (e.g., an inwardly facing surface of the substrate 100 or, in other words, a surface facing an interior of the housing of the article). Thus, the at least one visual element 210-1 may be seen by the user through the substrate 100 but the at least one visual element 210-1 is protected from wear or damage by way of being disposed on the inwardly facing surface (i.e., the second major surface) 104 of the substrate 100.

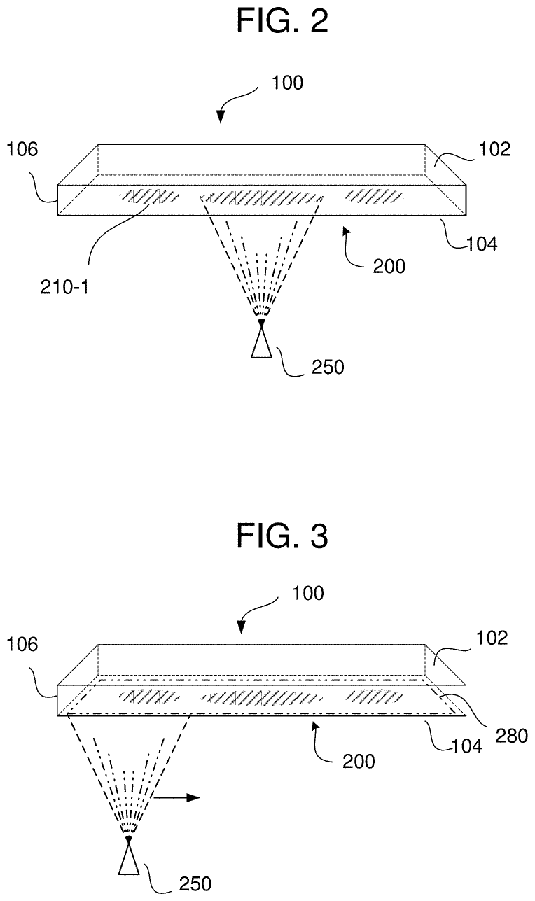

A process for application of the at least one visual element 210-1 directly to the substrate 100 will be discussed with reference to FIGS. 2-3, which contain schematic drawings of a substrate 100 as it moves through the process. As shown in FIG. 2, the at least one visual element 210-1 is applied via at least one first layer of imaging material directly to the imaging area 200 of the second major surface 104 of the substrate 100. In this example, and those that follow, it is assumed that the imaging area 200 extends all the way to the peripheral edges of the second major surface 104 of the substrate 200. The application of imaging material (and/or omission of imaging material as the case may be) is carried out to both the background 202 and foreground elements of the at least one visual element 210-1 to achieve the desired visual effects within the imaging area.

Such application of imaging material may involve ink printing, ink spraying, coating techniques, photolithography, etc. via suitable equipment 250 known to skilled artisans. As will be discussed in more detail below, the at least one first layer of imaging material may include multiple layers of such imaging material built up one over another. Irrespective of the particular technique employed, the imaging material applied directly to the second major surface 104 of the substrate 100 achieves the aforementioned one or more visual elements 210-1 (background 202 and foreground elements) arranged into at least one of: (i) one or more areas of color (or hue), (ii) one or more lines, (iii) one or more patterns, (iv) one or more designs, (v) one or more images, or (vi) one or more combinations thereof.

With reference to FIG. 3, a process for enhancing the visibility of the at least one visual element 210-1 through the first major surface 102 of the substrate 100 is carried out. For example, a bright (and preferably neutral) reflective layer 280 (also referred to herein as a backing layer), such as a light pigment (e.g., white), is applied over (e.g., behind) the at least one visual element 210-1 on the second major surface 104. The (backing) reflective layer 280 may be applied to the entire imaging area or a subset thereof. It is desirable, however, that the (backing) reflective layer 280 at least be applied over (e.g., behind) most, and preferably all, of the foreground. The (backing) reflective layer 280 may be applied by way of printing, coating, spraying, etc. using suitable equipment 250 known to skilled artisans. The (backing) reflective layer 280 may be formed from a light pigment (e.g., white), a shiny dark pigment (e.g., black), and/or a metallic coating, etc.

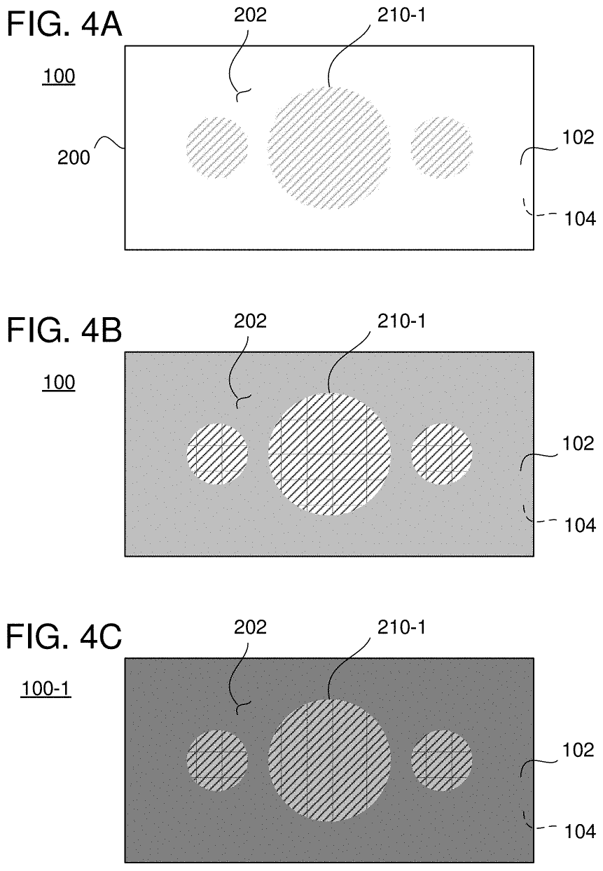

With reference to FIGS. 4A, 4B, and 4C, further details are presented in connection with the process for applying the at least one visual element 210-1 to the substrate 100. In one or more embodiments, the details discussed with reference to FIGS. 4A, 4B, and 4C may be carried out in addition to, and/or alternatively to, the details of FIG. 2 discussed hereinabove. In particular, with reference to FIG. 4A, the process for forming the at least one visual element 210-1 may include applying the at least one first layer of imaging material (e.g., ink) within the image area 200 of one of the first and second major surfaces 102, 104 of the substrate 100. In some embodiments, the imaging material is applied to the second major surface 104 of the substrate 100, and the imaging area 200 is defined to extend over the entire surface 104 (it being understood, however, that the size and shape of the imaging area is not so limited).

The imaging material is applied such that a pattern is defined within the image area 200 by one or more areas of relatively lower optical densities of the imaging material (or lack thereof), including zero optical density, and one or more areas of relatively higher optical densities of the imaging material. For example, the at least one first layer of imaging material shown in FIG. 4A may include areas of relatively higher optical densities, specifically a pattern of hash lines (where imaging material has been applied) defining the three circles of the at least one visual element 210-1. Further, the at least one first layer of imaging material may include areas of relatively lower optical densities (e.g., zero optical density), such as in between the hash lines and surrounding the defined circles and/or the background 202 (where substantially no imaging material has been applied).

With reference to FIG. 4B, one or more second layers of the imaging material may be applied within the image area 200 and over the at least one first layer of the imaging material to further enhance the at least one visual element 210-1. Specifically, the one or more second layers may be applied in registration with the at least one first layer, such that the one or more areas of relatively lower optical densities of the imaging material and the one or more areas of relatively higher optical densities of the imaging material (of the respective layers) reinforce the elements, features, etc. of the at least one visual element 210-1. For example, and again with reference to FIG. 4B, the one or more second layers of the imaging material may be applied to the background 202 in a way to increase the relative optical densities of the areas surrounding the hash lines that define the circles, while maintaining relatively lower optical densities (e.g., substantially zero optical density) in the areas in between the hash lines. Further, the one or more second layers of the imaging material may be applied in a way to increase the relative optical densities of the hash lines themselves (e.g., by applying one or more further layers of ink to enhance the hash lines themselves).

Thus, by comparison to FIG. 4A, one can see in FIG. 4B that the application of the one or more second layers of the imaging material reinforced the elements, features, etc. of the at least one visual element 210-1, namely the characteristics and definition of the circles. Through further application of one or more second layers of imaging material, the one or more areas of relatively lower optical densities of the imaging material and the one or more areas of relatively higher optical densities of the imaging material may further reinforce the elements, features, etc. of the at least one visual element 210-1.

Irrespective of whether only the at least one first layer of imaging material is employed, or whether one or more second layers of imaging material are employed, to produce the at least one visual element 210-1, it has been found advantageous when the relatively lower optical densities of the imaging material fall within a range of one of: (i) less than about 3.0; (ii) less than about 2.0; and (iii) less than about 1.0. Additionally and/or alternatively, it has been found advantageous when the relatively higher optical densities of the imaging material fall within a range of one of: (i) about 2.0 or greater; and (ii) about 3.0 or greater. It has been found particularly advantageous in some embodiments when the relatively higher optical densities of the imaging material are about 3.0 or more (which is substantially opaque, transmitting substantially no light therethrough), and the relatively lower optical densities of the imaging material are less that than about 3.0. Additionally and/or alternatively, the one or more areas of relatively lower optical densities of the imaging material exhibit a minimum optical density. For example, the minimum optical density may include zero optical density (i.e., transparent). The noted optical densities may be measured using a commercially available densitometer.

With reference to FIG. 4C, at least one background layer of material is applied over an entirety of the image area 200 such that the at least one background layer of material increases optical densities of the entirety of the image area 200. In some embodiments, the at least one background layer of material may be applied to a subset of the image area 200. It is again noted that the size and shape of the imaging area 200 may be primarily matters of aesthetic choice, and thus the imaging area 200 may circumscribe a subset of the second major surface 104 of the substrate 100, or the imaging area 200 may extend all the way to the peripheral edge of the substrate 100. Thus, in some embodiments, the imaging area 200 may precisely circumscribe the foreground elements of the at least one visual element 210-1 (substantially excluding background 202), and in other embodiments the imaging area 200 may circumscribe both background 202 and foreground elements. Thus, the optical densities of all elements of the at least one visual element 210-1 are increased via the at least one background layer of material. In the illustrated example, even the areas in between the hash lines are covered by the at least one background layer of material (which were formerly of substantially zero optical density). The reason for, and the desired properties of, the at least one background layer of material will be discussed in more detail later herein. For now, it is noted that there are a number of additions and/or alternatives in connection with the characteristics of the at least one background layer of material.

For example, in one or more embodiments, the at least one background layer of the material may enhance the entirety of the image area 200 by a uniform change in optical density. Alternatively, the at least one background layer of the material may increase the optical densities of respective areas of the image area by one or more differing magnitudes.

Additionally and/or alternatively, the at least one background layer may be formed of imaging material (e.g., ink), such as the same or similar material used in the at least one first layer of imaging material and/or the one or more second layers of imaging material. By way of example, in one or more embodiments, the imaging material of the at least first layer and the imaging material of the at least one background layer may be of a same, or substantially similar, color (or hue). Alternatively, the imaging material of the at least first layer may be of a first color (or hue) and the imaging material of the at least one background layer may be of a second, different color (or hue).

Additionally and/or alternatively, in one or more embodiments, the steps of applying the at least one first layer of imaging material, and applying the at least one background layer of material may be carried out in any order. Thus, for example, the application of the at least one background layer of material may take place prior to the application of the one or more first layers of the imaging material to the substrate 100. Additionally and/or alternatively, the application of the at least one background layer of material may take place among the application of the one or more first layers of the imaging material to the substrate 100. Additionally and/or alternatively, the application of the at least one background layer of material may take place after the application of the one or more first layers of the imaging material to the substrate 100.

In embodiments where the one or more second layers of imaging material are employed, the steps of applying the at least one second layer of imaging material, and applying the at least one background layer of material may also be carried out in any order. Thus, additionally and/or alternatively, the application of the at least one background layer of material may take place prior to the application of the one or more second layers of the imaging material to the substrate 100. Additionally and/or alternatively, the application of the at least one background layer of material may take place among the application of the one or more second layers of the imaging material to the substrate 100. Additionally and/or alternatively, the application of the at least one background layer of material may take place after the application of the one or more second layers of the imaging material to the substrate 100.

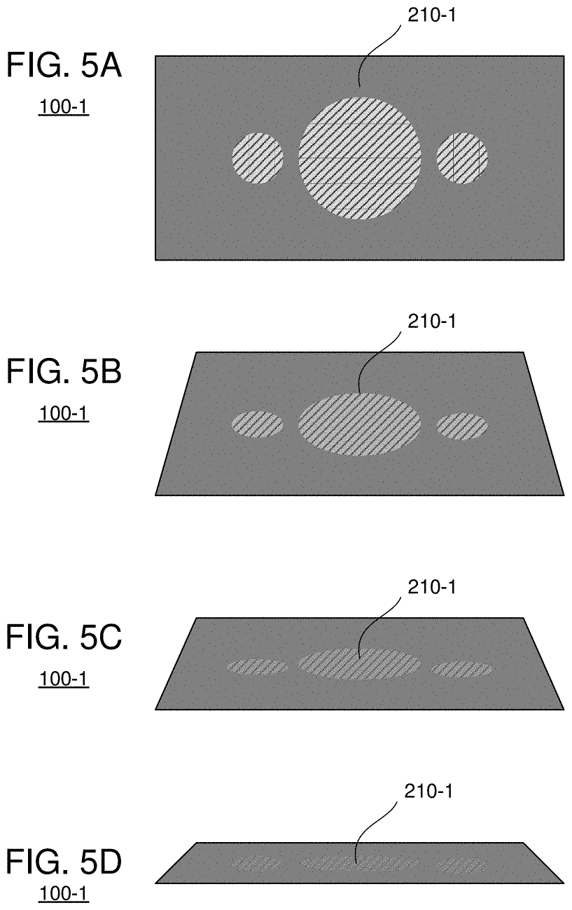

With reference to FIGS. 5A, 5B, 5C, and 5D, certain desirable features and characteristics of the at least one visual element 210-1 of the substrate 100-1 are shown for purposes of discussion. In connection with describing such features and characteristics, it is noted that FIG. 5A represents a zero degree viewing angle of the substrate 100-1 among a plurality of viewing angles. The zero viewing angle is defined to be normal to the first and second major surfaces 102, 104 of the substrate 110, and relatively higher viewing angles among the plurality of viewing angles are defined as being significantly acute (FIGS. 5B, 5C, and 5D) to the zero degree viewing angle (see, FIG. 5A). By way of example, a significantly acute angle may be greater than about 10 degrees, 20 degrees, 30 degrees, 40 degrees, 50 degrees, 60 degrees, 70 degrees, or 80 degrees.

As best seen in FIG. 5A, the at least one visual element 210-1 is visible through the substrate 100. In other words, at the zero viewing angle, a viewer can clearly see the one or more visual portions of the at least one visual element 210-1 arranged into at least one of: (i) one or more areas of color, (ii) one or more lines, (iii) one or more patterns, (iv) one or more designs, (v) one or more images, or (vi) one or more combinations thereof. This is so due to the light reflected by the backing layer, through the at least one background layer, through the at least first layer (and optionally the one or more second layers), and through the first major surface 102 of the substrate 100 at the zero viewing angle. This is also due to substrate 100 being partially transparent (or fully transparent) so that the imaging material applied to one major surface of substrate 100 (for example visual element 210-1) is visible when viewed through substrate 100 from the opposing major surface at a zero viewing angle.

As best seen in FIGS. 5B, 5C, and 5D, the visibility of the at least one visual element 210-1 through the substrate 100 decreases (and appears increasingly hidden) as the viewing angle changes from the zero viewing angle to the increasingly higher viewing angles. In some embodiments, at some viewing angles, the at least one visual element 210-1 may no longer be visible. The changes from visible to less visible (and vice versa) of the at least one visual element 210-1 through the substrate 100-1 provide dynamic, and highly desirable, optical features to the viewer.

The above-disclosed optical features produced by the substrate 100-1 may be characterized as mono-chromatic by way of using imaging material for the respective layers (e.g., the at least one first layer, the one or more second layers, and/or the background layer) of the same or substantially the same color (or hue).

Alternatively, additional optical features may be achieved when the imaging material of the at least one first layer (and/or the one or more second layers) is of a first color (or hue) and the imaging material of the at least one background layer is of a second, different color (or hue). In particular, at the zero viewing angle (FIG. 5A), the at least one visual element 210-1 may be visible in the first color (or hue). However, as the viewing angle changes from the zero viewing angle to the increasingly higher viewing angles (FIGS. 5B, 5C, and 5D), the at least one visual element 210-1 may be less visible in the first color (or hue) and more visible in at least one of: (i) a mix of the first and second colors (or hues), or (ii) the second color (or hue). Again, the changes in color (or hue) as a function of viewing angle of the substrate 100-1 provide dynamic, and highly desirable, optical features to the viewer. Again, in some embodiments, at some viewing angles, the at least one visual element 210-1 may no longer be visible. In some embodiments, the second color (or hue) may not be visible at the zero viewing angle.

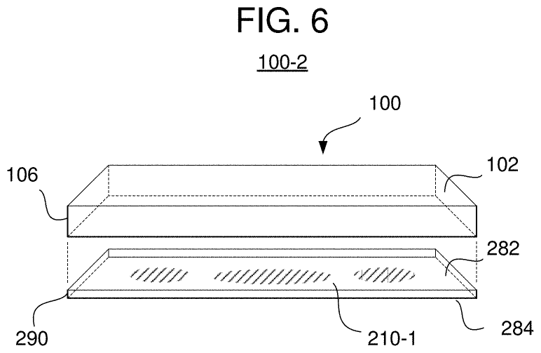

With reference to FIG. 6, an alternative structure 100-2 is disclosed with regards to the application of the at least one visual element 210-1 and a substrate 100. In particular, instead of (and/or in addition to) direct application of the at least one visual element 210-1 onto the second major surface 104 of the substrate 100, the at least one visual element 210-1 may be applied to a secondary substrate 290, such as to one (or both) of a first major surface 282 and a second major surface 284 thereof. Such application may be achieved using the aforementioned technique(s) with respect to FIGS. 2, 3, 4A, 4B, and 4C. The secondary substrate 290 is then combined with the substrate 100 to form the structure 100-2. In this regard, the at least one visual element 210-1 is indirectly applied to the second major surface 104 of the substrate 100.

The embodiments disclosed herein may be incorporated into a product, such as an article with a display (or display articles, such as consumer electronics, including mobile phones, watches tablets, computers, navigation systems, and the like), architectural articles, transportation articles (e.g., automotive, trains, aircraft, sea craft, etc.), appliance articles, or any article that may benefit from some transparency, visual enhancement, scratch-resistance, abrasion resistance or a combination thereof.

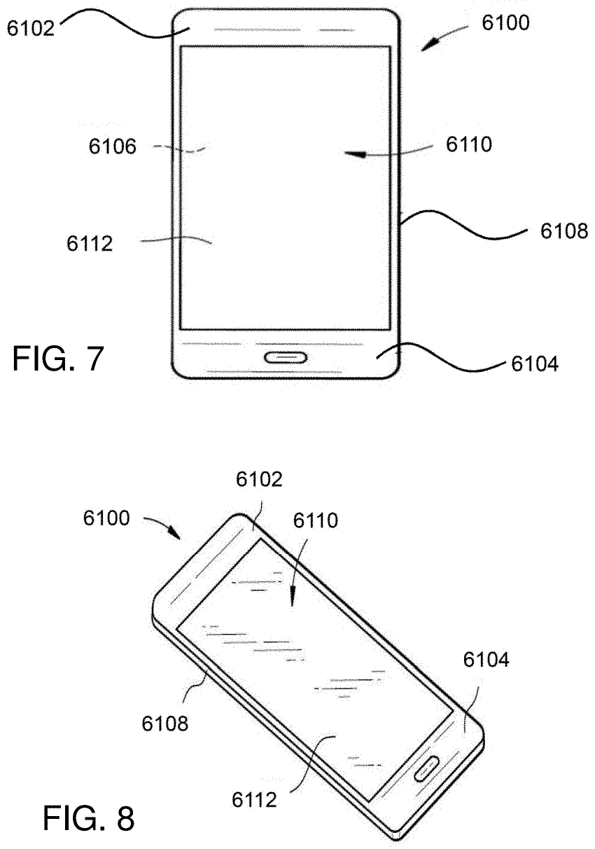

An exemplary article incorporating any number of the image improving features disclosed herein is shown in FIGS. 7 and 8. Specifically, FIGS. 7 and 8 show a consumer electronic device 6100 including a housing 6102 having front 6104, back 6106, and side surfaces 6108; electrical components (not shown) that are at least partially inside or entirely within the housing and including at least a controller, a memory, and a display 6110 at or adjacent to the front surface of the housing; and a cover substrate 6112 at or over the front surface of the housing such that the cover substrate 6112 is over the display.

In one or more embodiments, the cover substrate 6112 may include any of the image improving features disclosed herein.

In one or more embodiments, at least one of a portion of the housing 6102 and/or the cover substrate 6112 comprises the image improving features disclosed herein.

In an aspect 1, a method comprises:(a) applying at least a first layer of an imaging material within an image area of one of a first major surface and a second major surface of a substrate, such that a pattern is defined within the image area by one or more areas of relatively lower optical densities, including zero optical density, and one or more areas of relatively higher optical densities, where the second major surface is opposite the first major surface, the substrate includes at least one edge surface extending between the first and second major surfaces, and the first substrate is formed from an at least partially transparent material; and (b) applying at least one background layer of material over the image area such that the at least one background layer of material increases optical densities of the image area, wherein steps (a) and (b) may be carried out in any order.

An aspect 2 according to aspect 1, wherein the at least one background layer is formed of the imaging material.

An aspect 3 according to aspect 1 or 2, further comprising: (c) applying at least one backing layer of a reflective material over the at least first layer and the at least one background layer.

An aspect 4 according to aspect 3, wherein a zero degree viewing angle among a plurality of viewing angles is defined as normal to the first and second major surfaces of the substrate, and increasingly higher viewing angles among the plurality of viewing angles are defined as ranging from the zero degree viewing angle to increasingly larger acute angles relative to the zero degree viewing angle; and the pattern is visible through the substrate at the zero viewing angle by way of light reflected by the backing layer, through the at least one background layer, through the at least first layer, and through the substrate and the visibility of the pattern through the substrate decreases as the viewing angle changes from the zero viewing angle to the increasingly higher viewing angles.

An aspect 5 according to aspect 4, wherein the pattern is not visible through the substrate at some viewing angles.

An aspect 6 according to any preceding aspect, further comprising applying one or more second layers of the imaging material within the image area over the at least first layer to affect the pattern by application of the imaging material in registration with the one or more areas of relatively lower optical densities of the imaging material and the one or more areas of relatively higher optical densities of the imaging material, such that at least the one or more areas of relatively higher optical densities of the imaging material increase in optical density as compared with the one or more areas of relatively lower optical densities of the imaging material.

An aspect 7 according to any preceding aspect, wherein the relatively lower optical densities of the imaging material fall within a range of one of: (i) less than about 3.0; (ii) less than about 2.0; and (iii) less than about 1.0.

An aspect 8 according to any preceding aspect, wherein the relatively higher optical densities of the imaging material fall within a range of one of: (i) about 2.0 or greater; and (ii) about 3.0 or greater.

An aspect 9 according to any preceding aspect, wherein the one or more areas of relatively lower optical densities of the imaging material of the at least one first layer exhibits a minimum optical density.

An aspect 10 according to any preceding aspect, wherein the at least one background layer of material increases the image area by a uniform change in optical density.

An aspect 11 according to any preceding aspect, wherein the imaging material of the at least first layer and the imaging material of the at least one background layer are of a same color.

An aspect 12 according to any preceding aspect, wherein the imaging material of the at least first layer is of a first color and the imaging material of the at least one background layer is of a second, different color.

An aspect 13 according to aspect 12, wherein a zero degree viewing angle among a plurality of viewing angles is defined as normal to the first and second major surfaces of the substrate, and increasingly higher viewing angles among the plurality of viewing angles are defined as ranging from the zero degree viewing angle to increasingly larger acute angles relative to the zero degree viewing angle; and the first color of the pattern is visible through the substrate at the zero viewing angle by way of light reflected by the backing layer, through the at least one background layer, through the at least first layer, and through the substrate, and the visibility of the first color of the pattern through the substrate decreases and the visibility of at least one of: (i) a mix of the first and second colors, or (ii) the second color, through the substrate increases as the viewing angle changes from the zero viewing angle to the increasingly higher viewing angles.

An aspect 14 according to aspect 13, wherein at least one of: the first color of the pattern is not visible through the substrate at some viewing angles; or the second color of the pattern is not visible through the substrate at the same viewing angles.

An aspect 15 according to any preceding aspect, wherein the imaging material includes one or more inks, and the applying of the imaging material include an ink printing technique.

An aspect 16 according to any preceding aspect, wherein the substrate comprises one of glass material, glass-ceramic material, strengthened glass material, strengthened glass-ceramic material, and polymer material.

In an aspect 17, an apparatus comprises: a substrate having a first major surface, a second major surface opposite the first major surface, and at least one edge surface extending between the first and second major surfaces, where the first substrate is formed from an at least partially transparent material; at least a first layer of an imaging material applied within an image area of one of the first major surface and the second major surface of the substrate, such that a pattern is defined within the image area by one or more areas of relatively lower optical densities, including zero optical density, and one or more areas of relatively higher optical densities; and at least one background layer of material applied over the image area, where the at least one background layer of material increases optical densities of the image area.

An aspect 18 according to aspect 17, wherein the at least one background layer is formed of the imaging material.

An aspect 19 according to aspect 17 or 18, further comprising at least one backing layer of a reflective material applied over the at least first layer of an imaging material and the at least one background layer.

An aspect 20 according to any one of aspects 17-19, wherein a zero degree viewing angle among a plurality of viewing angles is defined as normal to the first and second major surfaces of the substrate, and increasingly higher viewing angles among the plurality of viewing angles are defined as ranging from the zero degree viewing angle to increasingly larger acute angles relative to the zero degree viewing angle; and the pattern is visible through the substrate by way of light reflected by the backing layer, through the at least one background layer, through the at least first layer, and through the substrate at the zero viewing angle, and the pattern is less visible through the substrate as the viewing angle changes from the zero viewing angle to the increasingly higher viewing angles.

An aspect 21 according to aspect 20, wherein the pattern is not visible through the substrate at some viewing angles.

An aspect 22 according to any one of aspects 17-21, further comprising one or more second layers of the imaging material applied within the image area over the at least first layer to affect the pattern by application of the imaging material in registration with the one or more areas of relatively lower optical densities of the imaging material and the one or more areas of relatively higher optical densities of the imaging material, such that at least the one or more areas of relatively higher optical densities of the imaging material increase in optical density as compared with the one or more areas of relatively lower optical densities of the imaging material.

An aspect 23 according to aspect any one of aspects 17-22, wherein the relatively lower optical densities of the imaging material fall within a range of one of: (i) less than about 3.0; (ii) less than about 2.0; and (iii) less than about 1.0.

An aspect 24 according to any one of aspects 17-19, wherein the relatively higher optical densities of the imaging material fall within a range of one of: (i) about 2.0 or greater; and (ii) about 3.0 or greater.

An aspect 25 according to any one of aspects 17-24, wherein the one or more areas of relatively lower optical densities of the imaging material of the at least one first layer exhibits a minimum optical density.

An aspect 26 according to any one of aspects 17-25, wherein the at least one background layer of material increases the image area by a uniform change in optical density.

An aspect 27 according to any one of aspects 17-26, wherein the imaging material of the at least first layer and the imaging material of the at least one background layer are of a same color.

An aspect 28 according to any one of aspects 17-27, wherein the imaging material of the at least first layer if of a first color and the imaging material of the at least one background layer is of a second, different color.

An aspect 29 according to aspect 28, wherein a zero degree viewing angle among a plurality of viewing angles is defined as normal to the first and second major surfaces of the substrate, and increasingly higher viewing angles among the plurality of viewing angles are defined as ranging from the zero degree viewing angle to increasingly larger acute angles relative to the zero degree viewing angle; and the pattern is visible in the first color by way of light reflected by the backing layer, through the at least one background layer, through the at least first layer, and through the substrate at the zero viewing angle, and the pattern is less visible in the first color and increasingly visible in at least one of: (i) a mix of the first and second colors, or (ii) the second color, through the substrate as the viewing angle changes from the zero viewing angle to the increasingly higher viewing angles.

An aspect 30 according to aspect 29, wherein at least one of: the first color of the pattern is not visible through the substrate at some viewing angles; and the second color of the pattern is not visible through the substrate at the same viewing angles.

An aspect 31 according to any one of aspects 17-30, wherein the imaging material includes one or more inks.

An aspect 32 according to any one of aspects 17-31, wherein the substrate comprises one of glass material, glass-ceramic material, strengthened glass material, strengthened glass-ceramic material, and polymer material.

In an aspect 33, a consumer electronic product comprises: a housing comprising a front surface, a back surface and side surfaces; electrical components at least partially within the housing, the electrical components comprising at least a controller, a memory, and a display, the display at or adjacent the front surface of the housing; and a cover substrate disposed over the display, wherein at least one of a portion of the housing or the cover substrate comprises the apparatus of any one of aspects 17-32.

Although the disclosure herein has been described with reference to particular embodiments, it is to be understood that these embodiments are merely illustrative of the principles and applications of the embodiments herein. It is therefore to be understood that numerous modifications may be made to the illustrative embodiments and that other arrangements may be devised without departing from the spirit and scope of the present application.

1. A method, comprising:
(a) applying at least a first layer of an imaging material within an image area of one of a first major surface and a second major surface of a substrate, such that a pattern is defined within the image area by one or more areas of relatively lower optical densities, including zero optical density, and one or more areas of relatively higher optical densities, where the second major surface is opposite the first major surface, the substrate includes at least one edge surface extending between the first and second major surfaces, and the first substrate is formed from an at least partially transparent material; and
(b) applying at least one background layer of material over the image area such that the at least one background layer of material increases optical densities of the image area,
wherein steps (a) and (b) may be carried out in any order.

2. The method of claim 1, further comprising: (c) applying at least one backing layer of a reflective material over the at least first layer and the at least one background layer,
wherein a zero degree viewing angle among a plurality of viewing angles is defined as normal to the first and second major surfaces of the substrate, and increasingly higher viewing angles among the plurality of viewing angles are defined as ranging from the zero degree viewing angle to increasingly larger acute angles relative to the zero degree viewing angle; and
wherein the pattern is visible through the substrate at the zero viewing angle and the visibility of the pattern through the substrate decreases as the viewing angle changes from the zero viewing angle to the increasingly higher viewing angles.

3. The method of claim 1, further comprising applying one or more second layers of the imaging material within the image area over the at least first layer to affect the pattern by application of the imaging material in registration with the one or more areas of relatively lower optical densities of the imaging material and the one or more areas of relatively higher optical densities of the imaging material, such that at least the one or more areas of relatively higher optical densities of the imaging material increase in optical density as compared with the one or more areas of relatively lower optical densities of the imaging material.

4. The method of claim 1, wherein at least one of:
the relatively lower optical densities of the imaging material fall within a range of one of: (i) less than about 3.0; (ii) less than about 2.0; and (iii) less than about 1.0; or
the relatively higher optical densities of the imaging material fall within a range of one of: (i) about 2.0 or greater; and (ii) about 3.0 or greater.

5. The method of claim 1, wherein the at least one background layer of material increases the image area by a uniform change in optical density.

6. The method of claim 1, wherein the imaging material of the at least first layer and the imaging material of the at least one background layer are of a same color.

7. The method of claim 1, wherein the imaging material of the at least first layer is of a first color and the imaging material of the at least one background layer is of a second, different color, and
wherein a zero degree viewing angle among a plurality of viewing angles is defined as normal to the first and second major surfaces of the substrate, and increasingly higher viewing angles among the plurality of viewing angles are defined as ranging from the zero degree viewing angle to increasingly larger acute angles relative to the zero degree viewing angle; and
wherein the first color of the pattern is visible through the substrate at the zero viewing angle, and the visibility of the first color of the pattern through the substrate decreases and the visibility of at least one of: (i) a mix of the first and second colors, or (ii) the second color, through the substrate increases as the viewing angle changes from the zero viewing angle to the increasingly higher viewing angles.

8. The method of claim 7, wherein at least one of:
the first color of the pattern is not visible through the substrate at some viewing angles; or
the second color of the pattern is not visible through the substrate at the same viewing angles.

9. The method of claim 1, wherein the imaging material includes one or more inks, and the applying of the imaging material include an ink printing technique, and
wherein the substrate comprises one of glass material, glass-ceramic material, strengthened glass material, strengthened glass-ceramic material, and polymer material.

10. An apparatus, comprising:
a substrate comprising a first major surface, a second major surface opposite the first major surface, and at least one edge surface extending between the first and second major surfaces, where the first substrate is formed from an at least partially transparent material;
at least a first layer of an imaging material applied within an image area of one of the first major surface and the second major surface of the substrate, such that a pattern is defined within the image area by one or more areas of relatively lower optical densities, including zero optical density, and one or more areas of relatively higher optical densities; and
at least one background layer of material applied over the image area, where the at least one background layer of material increases optical densities of the image area.

11. The apparatus of claim 10, further comprising at least one backing layer of a reflective material applied over the at least first layer of an imaging material and the at least one background layer,
wherein a zero degree viewing angle among a plurality of viewing angles is defined as normal to the first and second major surfaces of the substrate, and increasingly higher viewing angles among the plurality of viewing angles are defined as ranging from the zero degree viewing angle to increasingly larger acute angles relative to the zero degree viewing angle; and
wherein the pattern is visible through the substrate at the zero viewing angle, and the pattern is less visible through the substrate as the viewing angle changes from the zero viewing angle to the increasingly higher viewing angles.

12. The apparatus of claim 10, further comprising one or more second layers of the imaging material applied within the image area over the at least first layer to affect the pattern by application of the imaging material in registration with the one or more areas of relatively lower optical densities of the imaging material and the one or more areas of relatively higher optical densities of the imaging material, such that at least the one or more areas of relatively higher optical densities of the imaging material increase in optical density as compared with the one or more areas of relatively lower optical densities of the imaging material.

13. The apparatus of claim 10, wherein at least one of:
the relatively lower optical densities of the imaging material fall within a range of one of: (i) less than about 3.0; (ii) less than about 2.0; and (iii) less than about 1.0; or
the relatively higher optical densities of the imaging material fall within a range of one of: (i) about 2.0 or greater; and (ii) about 3.0 or greater.

14. The apparatus of claim 10, wherein the at least one background layer of material increases the image area by a uniform change in optical density.

15. The apparatus of claim 10, wherein the imaging material of the at least first layer and the imaging material of the at least one background layer are of a same color.

16. The apparatus of claim 10, wherein the imaging material of the at least first layer if of a first color and the imaging material of the at least one background layer is of a second, different color,
wherein a zero degree viewing angle among a plurality of viewing angles is defined as normal to the first and second major surfaces of the substrate, and increasingly higher viewing angles among the plurality of viewing angles are defined as ranging from the zero degree viewing angle to increasingly larger acute angles relative to the zero degree viewing angle; and
wherein the pattern is visible in the first color at the zero viewing angle, and the pattern is less visible in the first color and increasingly visible in at least one of: (i) a mix of the first and second colors, or (ii) the second color, through the substrate as the viewing angle changes from the zero viewing angle to the increasingly higher viewing angles.

17. The apparatus of claim 16, wherein at least one of:
the first color of the pattern is not visible through the substrate at some viewing angles; or
the second color of the pattern is not visible through the substrate at the same viewing angles.

18. The apparatus of claim 10, wherein the imaging material includes one or more inks, and
wherein the substrate comprises one of glass material, glass-ceramic material, strengthened glass material, strengthened glass-ceramic material, and polymer material.

19. A consumer electronic product, comprising:
a housing comprising a front surface, a back surface and side surfaces;
electrical components at least partially within the housing, the electrical components comprising at least a controller, a memory, and a display, the display at or adjacent the front surface of the housing; and
a cover substrate disposed over the display,
wherein at least one of a portion of the housing or the cover substrate comprises the apparatus of claim 10.
